(19) United States
(12) Patent Application Publication
(10) Pub. No.: US 2024/0147166 A1
(43) Pub. Date: May 2, 2024

(54) PLANAR PIEZOELECTRIC VIBRATION MODULE

(71) Applicant: OMVO TECHNOLOGY INC., Zhubei City (TW)

(72) Inventors: HSIANG LUN HSU, Miaoli City (TW); YI HSUN GUU, Hsinchu City (TW); YUE SHIH JENG, Jhubei City (TW)

(21) Appl. No.: 18/200,581

(22) Filed: May 23, 2023

Related U.S. Application Data
(60) Provisional application No. 63/345,409, filed on May 24, 2022.

(51) Int. Cl. H04R 17/00; H10N 30/50; H10N 30/87; H10N 30/88

(52) U.S. Cl. CPC H04R 17/00; H10N 30/50; H10N 30/871; H10N 30/88

(57) ABSTRACT

A planar piezoelectric vibration module includes an insulating bottom layer, a conductive layer, a piezoelectric assembly, and an insulating filling layer. The conductive layer is arranged on the insulating bottom layer and includes two conductive patterns that are insulated. The piezoelectric assembly is arranged on the conductive layer and includes a piezoelectric material layer, a first electrode including a first inner interdigital portion, a second electrode including a second inner interdigital portion, and an encapsulating material, where the first inner interdigital portion and the second inner interdigital portion penetrate through the piezoelectric material layer in a mutual interdigital arrangement manner, and the first electrode and the second electrode are electrically connected to the two conductive patterns, respectively. The insulating filling layer is arranged on the conductive layer and around the piezoelectric assembly. The planar piezoelectric vibration module has the advantage of achieving high-frequency and broadband transmission of sound waves.

### FIELD OF THE INVENTION

The present invention relates to a vibration module, and more particularly to a planar piezoelectric vibration module.

### BACKGROUND OF THE INVENTION

With the development trend of thin and light electronic products, speakers are gradually becoming thinner, and the demand for flat speakers is rapidly increasing with the market of electronic products. How to ensure the quality of sounds and consider sufficient thinness and quality to facilitate integration into the electronic products has become a key point of the technological development for new speaker products. In addition to the requirements for the thinness of the flat speakers and the difficulty in separation of internal components, broadband processing of audio frequency range is also an important topic for the subsequent development of piezoelectric speaker technology. Under the condition of the requirements for broadband processing, the audio frequency response of a speaker should have a wider range, and the sound pressure level of each frequency must also be maintained to be in a sufficiently close state, to avoid excessive fluctuation in low and high tones. Therefore, providing a piezoelectric flat speaker (i.e., a piezoelectric vibration module) with a wide vocal range and bandwidth is highly sought after by previous practitioners.

### SUMMARY OF THE INVENTION

The present invention provides a planar piezoelectric vibration module, which can be formed into a thin modular assembly and has the advantage of achieving high-frequency and broadband transmission of sound waves.

The planar piezoelectric vibration module provided by the present invention includes an insulating bottom layer, a first conductive layer, a first piezoelectric assembly, and an insulating filling layer. The first conductive layer is arranged on the insulating bottom layer and includes a first conductive pattern, a second conductive pattern, and an insulating groove, where the insulating groove is provided between the first conductive pattern and the second conductive pattern. The first piezoelectric assembly is arranged on the first conductive layer and includes a first piezoelectric material layer, a first electrode, a second electrode, and a first encapsulating material, where the first piezoelectric material layer includes a first surface and a second surface opposite to each other and a first side wall and a second side wall opposite to each other, the first side wall and the second side wall are connected to the first surface and the second surface, the first side wall faces the second side wall in a first direction, and the second side wall faces the first side wall in a second direction; the first electrode includes a first side portion, a first outer interdigital portion, and a first inner interdigital portion, the first outer interdigital portion and the first inner interdigital portion are connected to the first side portion, the first side portion is arranged on the first side wall, the first outer interdigital portion covers part of the first surface, the first inner interdigital portion penetrates through the first piezoelectric material layer along the first direction, and the first outer interdigital portion is electrically connected to the first conductive pattern; the second electrode is electrically connected to the second conductive pattern and includes a second side portion, a second outer interdigital portion, and a second inner interdigital portion, the second outer interdigital portion and the second inner interdigital portion are connected to the second side portion, the second side portion is arranged on the second side wall, the second outer interdigital portion covers part of the second surface, the second inner interdigital portion penetrates through the first piezoelectric material layer along the second direction, and the first outer interdigital portion, the second inner interdigital portion, the first inner interdigital portion, and the second outer interdigital portion are arranged in a mutual interdigital manner; and the first encapsulating material wraps the first piezoelectric material layer, part of the first electrode, and part of the second electrode, and exposes at least the first outer interdigital portion and the second outer interdigital portion. The insulating filling layer is arranged on the first conductive layer and at least around the at least a first piezoelectric assembly.

In an embodiment of the present invention, an extension length of the above first inner interdigital portion in the first direction is equal to an extension length of the second outer interdigital portion in the second direction, and an extension length of the second inner interdigital portion in the second direction is equal to an extension length of the first outer interdigital portion in the first direction.

In an embodiment of the present invention, the above insulating filling layer is further filled in the insulating groove, the planar piezoelectric vibration module further includes a conductive structure that penetrates through the insulating filling layer, and the second outer interdigital portion of the second electrode and the second conductive pattern are electrically connected by the conductive structure.

In an embodiment of the present invention, the above planar piezoelectric vibration module further includes a protective layer that is arranged on the insulating filling layer and covers the first piezoelectric assembly and the conductive structure.

In an embodiment of the present invention, the above first electrode further includes a first extended interdigital portion connected to the first side portion, and the first inner interdigital portion is located between the first outer interdigital portion and the first extended interdigital portion, where the first outer interdigital portion of the first electrode covers part of the first surface, the first extended interdigital portion and the second outer interdigital portion of the second electrode jointly cover the second surface, and there is a second gap between the first extended interdigital portion and the second outer interdigital portion.

In an embodiment of the present invention, a coverage area of the above second outer interdigital portion on the second surface is greater than a coverage area of the first extended interdigital portion on the second surface, and an extension length of the second outer interdigital portion in the second direction is less than an extension length of the second inner interdigital portion in the second direction.

In an embodiment of the present invention, a coverage area of the above first extended interdigital portion on the second surface is greater than a coverage area of the second outer interdigital portion on the second surface, and an extension length of the first extended interdigital portion in the first direction is less than an extension length of the first inner interdigital portion in the first direction.

In an embodiment of the present invention, the above insulating filling layer is further filled in the insulating groove, the planar piezoelectric vibration module further includes a conductive structure that penetrates through the insulating filling layer, and the second outer interdigital portion of the second electrode and the second conductive pattern are electrically connected by the conductive structure.

In an embodiment of the present invention, the above conductive structure is further electrically connected to the first extended interdigital portion of the first electrode and the first conductive pattern.

In an embodiment of the present invention, the above planar piezoelectric vibration module further includes a protective layer that is arranged on the insulating filling layer, where the protective layer covers the first piezoelectric assembly and the conductive structure, and fills the second gap.

In an embodiment of the present invention, the above first electrode further includes a first extended interdigital portion connected to the first side portion, and the first inner interdigital portion is located between the first outer interdigital portion and the first extended interdigital portion; the second electrode further includes a second extended interdigital portion connected to the second side portion, and the second inner interdigital portion is located between the second outer interdigital portion and the second extended interdigital portion, where the first outer interdigital portion of the first electrode and the second extended interdigital portion of the second electrode jointly cover the first surface, and there is a first gap between the first outer interdigital portion and the second extended interdigital portion; and the first extended interdigital portion of the first electrode and the second outer interdigital portion of the second electrode jointly cover the second surface, and there is a second gap between the first extended interdigital portion and the second outer interdigital portion.

In an embodiment of the present invention, a coverage area of the above second outer interdigital portion on the second surface is greater than a coverage area of the first extended interdigital portion on the second surface, and a coverage area of the first outer interdigital portion on the first surface is greater than a coverage area of the second extended interdigital portion on the first surface.

In an embodiment of the present invention, the second extended interdigital portion of the above second electrode is electrically connected to the second conductive pattern, and the first encapsulating material is further filled in one part of the insulating groove and the first gap.

In an embodiment of the present invention, the above planar piezoelectric vibration module further includes a protective layer that is arranged on the insulating filling layer, where the protective layer covers the first piezoelectric assembly and fills the second gap.

In an embodiment of the present invention, there are a plurality of above first piezoelectric assemblies, the planar piezoelectric vibration module further includes a conductive structure, the conductive structure includes a conductive column and a second conductive layer, the second conductive layer is electrically connected to the second outer interdigital portions of the first piezoelectric assemblies, and the conductive column penetrates through the insulating filling layer and is electrically connected to the second conductive layer and the second conductive pattern.

In an embodiment of the present invention, there are a plurality of above first piezoelectric assemblies, the planar piezoelectric vibration module further includes a plurality of conductive structures that penetrate through the insulating filling layer, and each of the conductive structures electrically connects the second outer interdigital portion of each of the piezoelectric assemblies to the second conductive pattern.

In an embodiment of the present invention, the above planar piezoelectric vibration module further includes a second piezoelectric assembly, where the second piezoelectric assembly includes a second piezoelectric material layer, a first planar electrode, a second planar electrode, and a second encapsulating material, the first planar electrode and the second planar electrode are arranged on two opposite sides of the second piezoelectric material layer, respectively, the second encapsulating material wraps part of the second piezoelectric material layer and exposes at least the first planar electrode and the second planar electrode, and the first planar electrode is electrically connected to the first conductive pattern; and the planar piezoelectric vibration module further includes a conductive structure, where the conductive structure includes a conductive column and a second conductive layer, the second conductive layer is electrically connected to the second planar electrode and the second outer interdigital portion, and the conductive column penetrates through the insulating filling layer and is electrically connected to the second conductive layer and the second conductive pattern.

In an embodiment of the present invention, the above planar piezoelectric vibration module further includes a second piezoelectric assembly, where the second piezoelectric assembly includes a second piezoelectric material layer, a first bent electrode, a second bent electrode, and a second encapsulating material. The second piezoelectric material layer includes a third surface and a fourth surface opposite to each other and a third side wall and a fourth side wall opposite to each other, where the third side wall and the fourth side wall are connected to the third surface and the fourth surface; the first bent electrode is arranged on part of the third surface and the third side wall; the second bent electrode is arranged on part of the fourth surface and the fourth side wall; the second encapsulating material wraps the second piezoelectric material layer, part of the first bent electrode, and part of the second bent electrode, where part of the first bent electrode located on the third surface is electrically connected to the first conductive pattern; and the planar piezoelectric vibration module further includes a plurality of conductive structures that penetrate through the insulating filling layer and electrically connect the second outer interdigital portion of the first piezoelectric assembly and part of the second bent electrode to the second conductive pattern, respectively.

In an embodiment of the present invention, the above conductive structures further electrically connect the first extended interdigital portion of the first piezoelectric assembly and part of the first bent electrode to the first conductive pattern, respectively.

In an embodiment of the present invention, the above second bent electrode further covers part of the third surface and has a third gap from the first bent electrode located on the third surface.

In an embodiment of the present invention, the above first bent electrode further covers part of the fourth surface and has a fourth gap from the second bent electrode located on the fourth surface.

In an embodiment of the present invention, the above first outer interdigital portion is arranged on the first conductive pattern by a bonding layer.

In an embodiment of the present invention, the above planar piezoelectric vibration module further includes a third conductive layer arranged on the other opposite side, away from the first conductive layer, of the insulating bottom layer.

In an embodiment of the present invention, the above planar piezoelectric vibration module further includes an auxiliary layer arranged on the other opposite side, away from the insulating bottom layer, of the third conductive layer.

According to the present invention, through the design of the inner interdigital portions, the planar piezoelectric assembly may have a plurality of layers of sub-piezoelectric bodies; and the sub-piezoelectric bodies may have different thicknesses and resonant frequencies, so that the planar piezoelectric assembly has various resonant frequencies. The resonant frequencies get close to each other and are coupled, and the simultaneous operation is performed within a wider frequency range, so that the combined frequency response does not generate discontinuous and deep troughs, and the composite multi-mode vibration will be formed within this frequency band, that is, the working bandwidth of the piezoelectric vibration module can be effectively expanded to achieve high-frequency and broadband transmission of sound waves.

In order to make the above and other objects, features and advantages of the present invention more comprehensible, the following specific embodiments are described in detail in conjunction with the accompanying drawings.

### BRIEF DESCRIPTION OF THE DRAWINGS

FIG. 1 is a schematic sectional view of a planar piezoelectric vibration module according to a first embodiment of the present invention.

FIG. 2 is a schematic sectional view of a planar piezoelectric vibration module according to a second embodiment of the present invention.

FIG. 3 is a schematic sectional view of a planar piezoelectric vibration module according to a third embodiment of the present invention.

FIG. 4 is a schematic sectional view of a planar piezoelectric vibration module according to a fourth embodiment of the present invention.

FIG. 5A and FIG. 5B are schematic sectional views of a planar piezoelectric vibration module according to a fifth embodiment of the present invention.

FIG. 6A and FIG. 6B are schematic sectional views of a planar piezoelectric vibration module according to a sixth embodiment of the present invention.

FIG. 7A and FIG. 7B are schematic sectional views of a planar piezoelectric vibration module according to a seventh embodiment of the present invention.

### DETAILED DESCRIPTION OF PREFERRED EMBODIMENTS

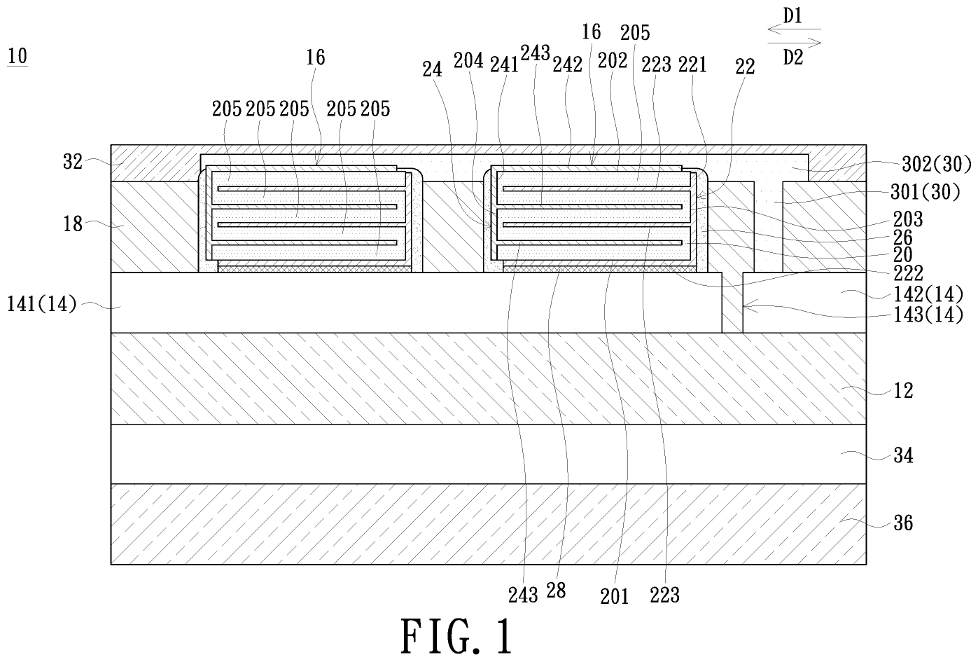

FIG. 1 is a schematic sectional view of a planar piezoelectric vibration module according to a first embodiment of the present invention. As shown in FIG. 1, a planar piezoelectric vibration module 10 includes an insulating bottom layer 12, a first conductive layer 14, a first piezoelectric assembly 16, and an insulating filling layer 18. A material of the insulating bottom layer 12 is, for example, a material such as a fiberglass epoxy laminate sheet (FR4), glass, polyethylene terephthalate (PET), or polyimide (PI), or a combination thereof, and a thickness of the insulating bottom layer 12 is, for example, between 10 microns and 100 microns. The first conductive layer 14 is arranged on the insulating bottom layer 12 and includes a first conductive pattern 141, a second conductive pattern 142, and an insulating groove 143, where the insulating groove 143 is provided between the first conductive pattern 141 and the second conductive pattern 142. In an embodiment, the insulating groove 143 penetrates through the first conductive layer 14 to separate the first conductive pattern 141 from the second conductive pattern 142, where a thickness of the first conductive layer 14 is, for example, between 10 microns and 50 microns. The first piezoelectric assembly 16 is arranged on the first conductive layer 14. There may be one or a plurality of first piezoelectric assemblies 16. The first piezoelectric assemblies 16 have different embodiments (as described later). The plurality of first piezoelectric assemblies 16 having the different embodiments or the same embodiment may be arranged on the first conductive layer 14 according to the requirements, or the first piezoelectric assemblies 16 may be arranged on the first conductive layer 14 in combination with second piezoelectric assemblies having different embodiments, etc. described later. The insulating filling layer 18 is arranged on the first conductive layer 14 and around the first piezoelectric assembly 16. In an embodiment, as shown in FIG. 1, the insulating filling layer 18 is filled between the plurality of first piezoelectric assemblies 16 (and/or the second piezoelectric assemblies described later).

Continuing with the above description, the first piezoelectric assembly 16 includes a first piezoelectric material layer 20, a first electrode 22, a second electrode 24, and a first encapsulating material 26. The first piezoelectric material layer 20 includes a first surface 201 and a second surface 202 opposite to each other and a first side wall 203 and a second side wall 204 opposite to each other, where the first side wall 203 and the second side wall 204 are connected to the first surface 201 and the second surface 202, the first side wall 203, for example, faces the second side wall 204 in a first direction D1, and the second side wall 204, for example, faces the first side wall 203 in a second direction D2, that is, the first direction D1 and the second direction D2 are parallel and opposite directions. In an embodiment, the first piezoelectric material layer 20 is, for example, a piezoelectric ceramic material, and a thickness between the first surface 201 and the second surface 202 thereof is, for example, between 5 microns and 300 microns.

The first electrode 22 includes a first side portion 221, a first outer interdigital portion 222, and a first inner interdigital portion 223, where the first outer interdigital portion 222 and the first inner interdigital portion 223 are connected to the first side portion 221. In an embodiment, there may be one or a plurality of first inner interdigital portions 223 (there are two first inner interdigital portions as shown in FIG. 1), and the first inner interdigital portion 223 is parallel to and spaced from the first outer interdigital portion 222, where the first outer interdigital portion 222 is arranged at one end of the first side portion 221, and the plurality of first inner interdigital portions 223 are, for example, connected at intervals to the first side portion 221. As shown in FIG. 1, the first side portion 221 is arranged on the first side wall 203 of the first piezoelectric material layer 20, where the first outer interdigital portion 222 covers part of the first surface 201, and the first inner interdigital portion 223 penetrates through the first piezoelectric material layer 20 along the first direction D1. In an embodiment, a thickness of the first side portion 221 and the first inner interdigital portion 223 is, for example, between 1 micron and 10 microns, and a thickness of the first outer interdigital portion 222 is, for example, between 5 microns and 20 microns.

The second electrode 24 includes a second side portion 241, a second outer interdigital portion 242, and a second inner interdigital portion 243, where the second outer interdigital portion 242 and the second inner interdigital portion 243 are connected to the second side portion 241. In an embodiment, there may be one or a plurality of second inner interdigital portions 243 (there are two inner interdigital portions as shown in FIG. 1), preferably, the number of second inner interdigital portions 243 is equal to the number of first inner interdigital portions 223, or the number of second inner interdigital portions 243 differs by one from the number of first inner interdigital portions 223. In an embodiment, the plurality of second inner interdigital portions 243 are, for example, connected at intervals to the second side portion 241. The second outer interdigital portion 242 is arranged at one end of the second side portion 241 and is parallel to and spaced from the second inner interdigital portion 243. As shown in FIG. 1, the second side portion 241 is arranged on the second side wall 204 of the second piezoelectric material layer 20, where the second outer interdigital portion 242 covers part of the second surface 202, the second inner interdigital portion 243 penetrates through the first piezoelectric material layer 20 along the second direction D2, and the first outer interdigital portion 222, the second inner interdigital portion 243, the first inner interdigital portion 223, and the second outer interdigital portion 242 are arranged in a mutual interdigital manner. In an embodiment, a thickness of the second side portion 241 and the second inner interdigital portion 243 is, for example, between 1 micron and 10 microns, and a thickness of the second outer interdigital portion 242 is, for example, between 5 microns and 20 microns.

The first encapsulating material 26 wraps the first piezoelectric material layer 20, part of the first electrode 22, and part of the second electrode 24, and exposes at least the first outer interdigital portion 222 and the second outer interdigital portion 242. In an embodiment, the first encapsulating material 26 is, for example, an insulating adhesive material. Continuing with reference to FIG. 1, the first electrode 22 is electrically connected to the first conductive pattern 141, where the first outer interdigital portion 222 of the first electrode 22 is, for example, directly adhered to the first conductive pattern 141 by an extremely thin bonding layer 28; and the second electrode 24 is electrically connected to the second conductive pattern 142, and the second outer interdigital portion 242 of the second electrode 24 is, for example, connected to the second conductive pattern 142 by a conductive structure 30 that penetrates through the insulating filling layer 18.

In an embodiment, an extension length of the first inner interdigital portion 223 in the first direction D1 is equal to an extension length of the second outer interdigital portion 242 in the second direction D2, and an extension length of the second inner interdigital portion 243 in the second direction D2 is equal to an extension length of the first outer interdigital portion 222 in the first direction D1. It can be understood that the mutual interdigital arrangement of the first inner interdigital portion 223 and the second inner interdigital portion 243 can divide the first piezoelectric material layer 20 into a plurality of sub-piezoelectric bodies 205. For example, the first piezoelectric assembly 16 shown in FIG. 1 includes five layers of sub-piezoelectric bodies 205 (marked on the first piezoelectric assembly 16 located on a left side), where the first inner interdigital portion 223 (or the first outer interdigital portion 222) electrically connected to the first conductive pattern 141 and the second inner interdigital portion 243 (or the second outer interdigital portion 242) electrically connected to the second conductive pattern 142 are arranged on two opposite sides of each layer of sub-piezoelectric body 205.

Continuing with the above description, as shown in FIG. 1, a thickness of the insulating filling layer 18 is, for example, between 10 microns and 200 microns, where the insulating filling layer 18 is further filled in the insulating groove 143 to strengthen the insulation of the first conductive pattern 141 and the second conductive pattern 142. In addition, the above conductive structure 30 includes, for example, a conductive column 301 and a second conductive layer 302, where the second conductive layer 302 is electrically connected to the second outer interdigital portions 242 of the plurality of first piezoelectric assemblies 16, the conductive column 301 penetrates through the insulating filling layer 18 and is electrically connected to the second conductive layer 302 and the second conductive pattern 142, and a thickness of the second conductive layer 302 is, for example, between 10 microns and 50 microns.

Continuing with reference to FIG. 1, in an embodiment, the planar piezoelectric vibration module 10 further includes a protective layer 32 that is arranged on the insulating filling layer 18 and covers the first piezoelectric assembly 16 and the conductive structure 30; and a thickness of the protective layer 32 is, for example, between 2 microns and 500 microns. In an embodiment, the planar piezoelectric vibration module 10 further includes a third conductive layer 34 and an auxiliary layer 36, where the third conductive layer 34 is arranged on the other opposite side, away from the first conductive layer 14, of the insulating bottom layer 12, and the auxiliary layer 36 is arranged on the other opposite side, away from the insulating bottom layer 12, of the third conductive layer 34. A thickness of the third conductive layer 34 is, for example, between 10 microns and 50 microns, a thickness of the auxiliary layer 36 is, for example, between 10 microns and 200 microns, and the auxiliary layer 36 is, for example, an insulating layer. Through the selection and stacking of the auxiliary layer 36, the problem of layering or bending of the planar piezoelectric vibration module 10 due to deformation can be reduced.

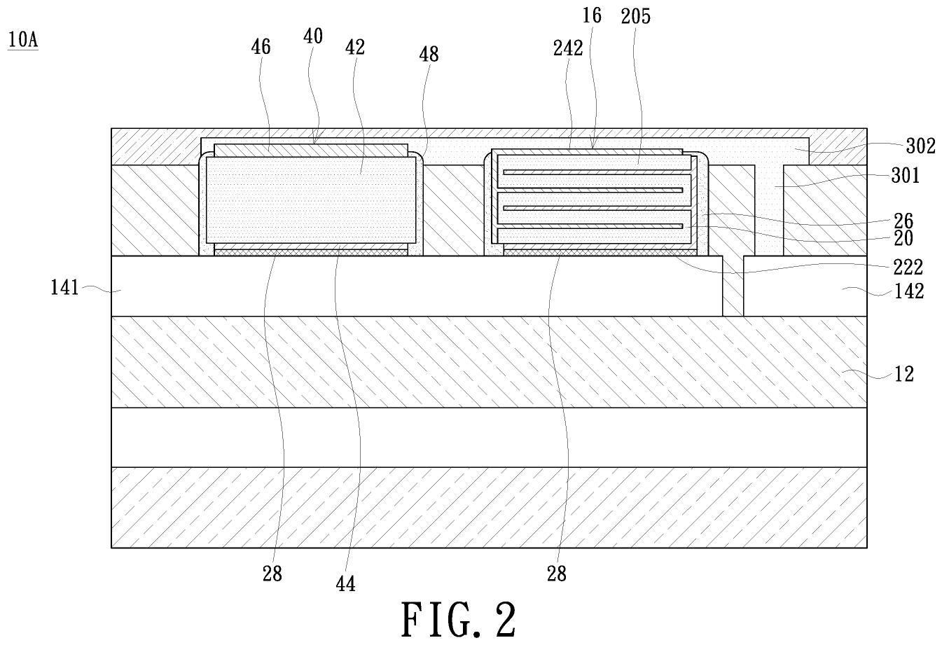

FIG. 2 is a schematic sectional view of a planar piezoelectric vibration module according to a second embodiment of the present invention. As shown in FIG. 2, there is a difference between a planar piezoelectric vibration module 10A according to a second embodiment and the planar piezoelectric vibration module 10 according to the first embodiment that the planar piezoelectric vibration module 10A according to the second embodiment further includes a second piezoelectric assembly 40. It can be understood that the second piezoelectric assemblies 40 can replace one or a plurality of groups of first piezoelectric assemblies 16 of the planar piezoelectric vibration module 10 according to the first embodiment. In FIG. 2, for example, there are one group of first piezoelectric assemblies 16 and one group of second piezoelectric assemblies 40, but are not limited thereto. As shown in FIG. 2, the second piezoelectric assembly 40 includes a second piezoelectric material layer 42, a first planar electrode 44, a second planar electrode 46, and a second encapsulating material 48, where the first planar electrode 44 and the second planar electrode 46 are arranged on two opposite sides of the second piezoelectric material layer 42, respectively, and the second encapsulating material 48 wraps part of the second piezoelectric material layer 42 and exposes at least the first planar electrode 44 and the second planar electrode 46.

Continuing with the above description, in correspondence to the first outer interdigital portion 222 of the first piezoelectric assembly 16, the first planar electrode 44 of the second piezoelectric assembly 40 is electrically connected to the first conductive pattern 141, where the first planar electrode 44 is, for example, also directly adhered to the first conductive pattern 141 by an extremely thin bonding layer 28. In addition, the second planar electrode 46 of the second piezoelectric assembly 40 and the second outer interdigital portion 242 of the first piezoelectric assembly 16 are electrically connected by the second conductive layer 302, so that the second planar electrode 46 and the second outer interdigital portion 242 can be electrically connected to the second conductive pattern 142 by the second conductive layer 302 and the conductive column 301.

In other words, the first piezoelectric assembly 16 and the second piezoelectric assembly 40 may be optionally arranged in the planar piezoelectric vibration module 10A according to the second embodiment, where the second piezoelectric assembly 40 includes a layer of piezoelectric body (i.e. the second piezoelectric material layer 42), the first piezoelectric assembly 16 includes a plurality of layers (such as five layers) of sub-piezoelectric bodies 205, and the number of first piezoelectric assemblies 16 and the number of second piezoelectric assemblies 40 are not limited to one, so that two or a plurality of first piezoelectric assemblies 16 or two or a plurality of second piezoelectric assemblies 40 can be arranged as required. The first outer interdigital portion 222 (or the first planar electrode 44) and the second outer interdigital portion 242 (or the second planar electrode 46) are located on two opposite sides of the first piezoelectric material layer 20 (or the second piezoelectric material layer 42), but are not limited thereto.

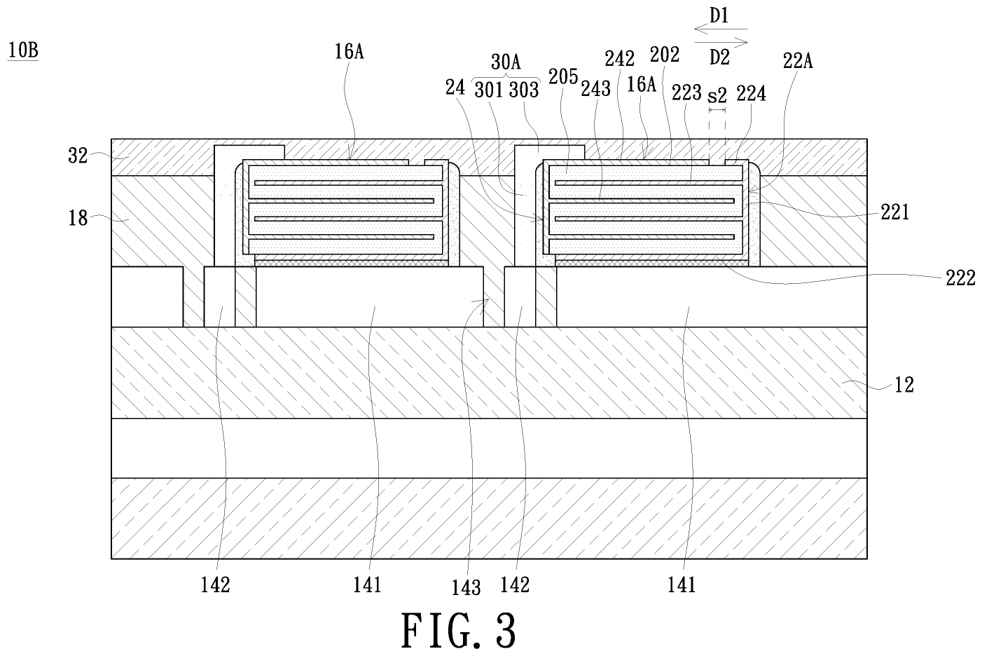

FIG. 3 is a schematic sectional view of a planar piezoelectric vibration module according to a third embodiment of the present invention. There is a difference between a planar piezoelectric vibration module 10B according to a third embodiment and the planar piezoelectric vibration module 10 according to the first embodiment that the planar piezoelectric vibration module 10B according to the third embodiment has first piezoelectric assemblies 16A of different structures, and a difference between the first piezoelectric assembly 16A and the first piezoelectric assembly 16 lies in a first electrode 22A. As shown in FIG. 3, the first electrode 22A includes a first extended interdigital portion 224 in addition to the first side portion 221, the first outer interdigital portion 222, and the first inner interdigital portion 223. The first extended interdigital portion 224, the first inner interdigital portion 223, and the first outer interdigital portion 222 are connected to the first side portion 221, and the first inner interdigital portion 223 is located between the first outer interdigital portion 222 and the first extended interdigital portion 224. In an embodiment, an extension length of the first extended interdigital portion 224 in the first direction D1 is less than an extension length of the first inner interdigital portion 223 in the first direction D1, and the first extended interdigital portion 224 and the second outer interdigital portion 242 of the second electrode 24 jointly cover the second surface 202, where there is a second gap s2 between the first extended interdigital portion 224 and the second outer interdigital portion 242.

Continuing with the above description, the planar piezoelectric vibration module 10B includes a conductive structure 30A, where the conductive structure 30A includes a plurality of conductive columns 301 and a plurality of second conductive sub-layers 303, and each of the plurality of second conductive sub-layers 303 is connected to the second outer interdigital portion 242 of each first piezoelectric assembly 16A. As shown in FIG. 3, the plurality of conductive columns 301 penetrate through the insulating filling layer 18 near the first piezoelectric assembly 16A, respectively, the conductive columns 301 have one terminal connected to the second conductive sub-layers 303 and the other terminal connected to the second conductive pattern 142, and the second outer interdigital portion 242 is electrically connected to the second conductive pattern 142 by the conductive structure 30A. It can be understood that in the planar piezoelectric vibration module 10B according to the third embodiment, the first conductive pattern 141 and the second conductive pattern 142 are staggered through the distribution of the insulating groove 143, where the first outer interdigital portion 222 of the first piezoelectric assembly 16A is directly electrically connected to the first conductive pattern 141, and the second outer interdigital portion 242 is electrically connected to the second conductive pattern 142 by the conductive structure 30A. Additionally, in an embodiment, the planar piezoelectric vibration module 10B further includes a protective layer 32 that is arranged on the insulating filling layer 18, covers the first piezoelectric assemblies 16A and the plurality of second conductive sub-layers 303, and fills the second gap s2.

As shown in FIG. 3, for example, the first piezoelectric assembly 16A includes five layers of sub-piezoelectric bodies 205. In an embodiment, a coverage area of the second outer interdigital portion 242 on the second surface 202 is greater than a coverage area of the first extended interdigital portion 224 on the second surface 202, where one side of the sub-piezoelectric body 205 farthest away from the insulating bottom layer 12 is covered with a large area of the second outer interdigital portion 242, and the other side thereof is covered with the first inner interdigital portion 223, so that although the sub-piezoelectric body 205 farthest away from the insulating bottom layer 12 is covered with the first extended interdigital portion 224, electrical signals are still provided by the second outer interdigital portion 242 electrically connected to the second conductive pattern 142 and the first inner interdigital portion 223 electrically connected to the first conductive pattern 141. In addition, the extension length of the second outer interdigital portion 242 in the second direction D2 is less than the extension length of the second inner interdigital portion 243 in the second direction D2.

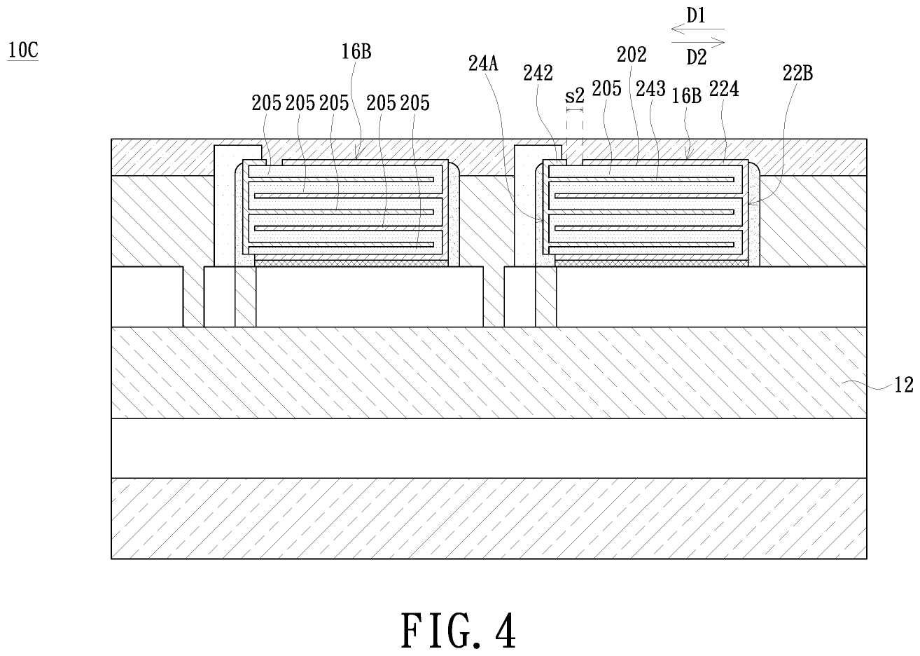

FIG. 4 is a schematic sectional view of a planar piezoelectric vibration module according to a fourth embodiment of the present invention. There is a difference between a planar piezoelectric vibration module 10C according to a fourth embodiment and the planar piezoelectric vibration module 10B according to the third embodiment that the planar piezoelectric vibration module 10C according to the fourth embodiment has first piezoelectric assemblies 16B of different structures, where the first piezoelectric assembly 16B has a first electrode 22B and a second electrode 24A of different structures. As shown in FIG. 4, for example, the first piezoelectric assembly 16B includes six layers of sub-piezoelectric bodies 205 (marked on the first piezoelectric assembly 16B located on the left side), and the first extended interdigital portion 224 of the first electrode 22B and the second outer interdigital portion 242 of the second electrode 24A jointly cover the second surface 202, where the coverage area of the first extended interdigital portion 224 on the second surface 202 is greater than the coverage area of the second outer interdigital portion 242 on the second surface 202. One side of the sub-piezoelectric body 205 farthest away from the insulating bottom layer 12 is covered with a large area of the first extended interdigital portion 224, and the other side thereof is covered with the second inner interdigital portion 243 of the second electrode 24A, so that although the sub-piezoelectric body 205 farthest away from the insulating bottom layer 12 is covered with the second outer interdigital portion 242, electrical signals are still provided by the second inner interdigital portion 243 electrically connected to the second conductive pattern 142 and the first extended interdigital portion 224 electrically connected to the first conductive pattern 141. In addition, the extension length of the first extended interdigital portion 224 in the first direction D1 is less than the extension length of the first inner interdigital portion 223 in the first direction D1.

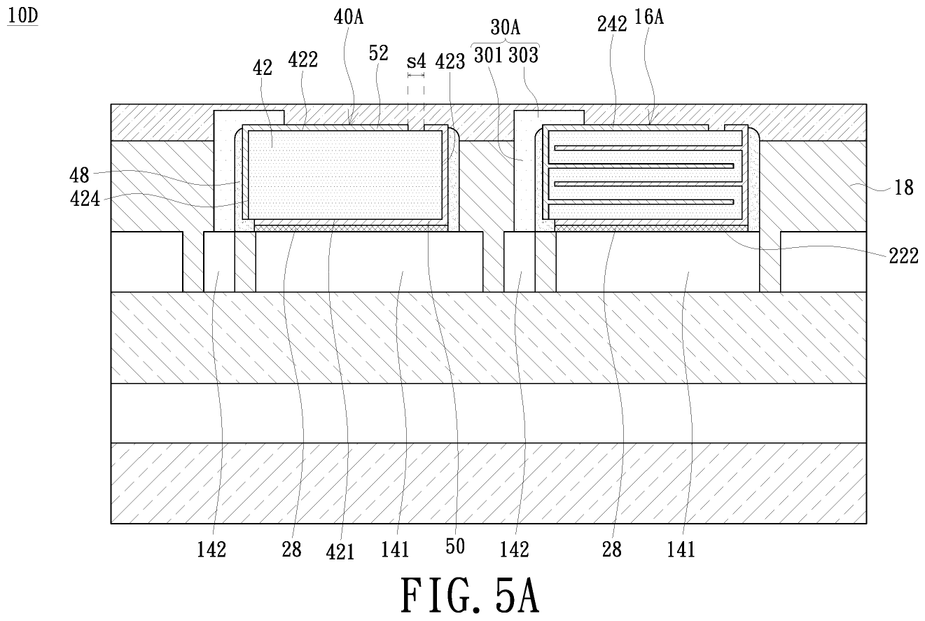

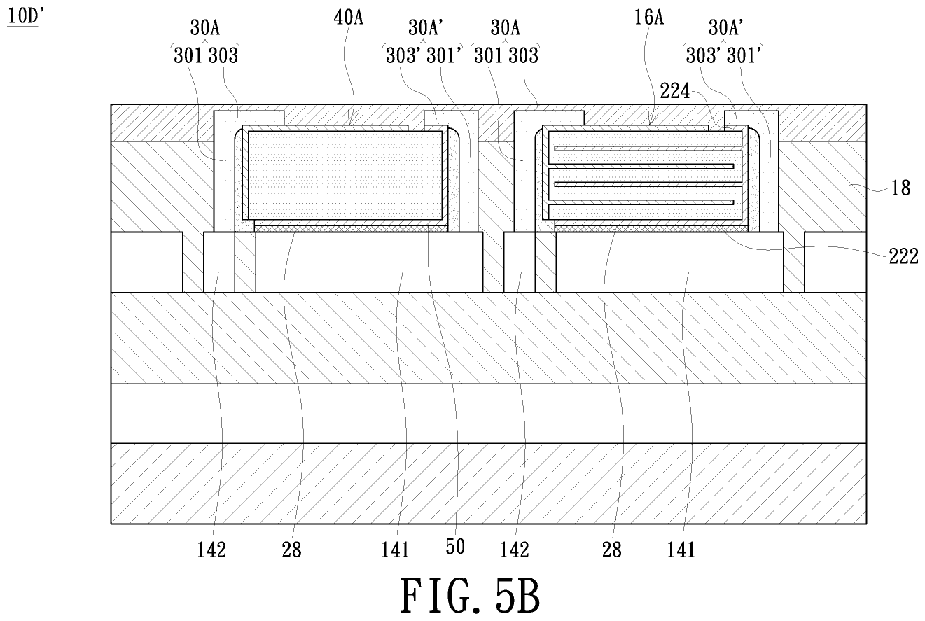

FIG. 5A and FIG. 5B are schematic sectional views of a planar piezoelectric vibration module according to a fifth embodiment of the present invention. As shown in FIG. 5A, there is a difference between a planar piezoelectric vibration module 10D according to a fifth embodiment and the planar piezoelectric vibration module 10B according to the third embodiment that the planar piezoelectric vibration module 10D according to the fifth embodiment further includes a second piezoelectric assembly 40A. It can be understood that the second piezoelectric assemblies 40A can replace one or a plurality of groups of first piezoelectric assemblies 16A/16B of the planar piezoelectric vibration module 10B/10C according to the third/fourth embodiment. In FIG. 5A, for example, there are one group of first piezoelectric assemblies 16A and one group of second piezoelectric assemblies 40A only, but are not limited thereto. The second piezoelectric assembly 40A includes a second piezoelectric material layer 42, a first bent electrode 50, a second bent electrode 52, and a third encapsulating material 48. The second piezoelectric material layer 42 includes a third surface 421 and a fourth surface 422 opposite to each other and a third side wall 423 and a fourth side wall 424 opposite to each other, where the third side wall 423 and the fourth side wall 424 are connected to the third surface 421 and the fourth surface 422; the first bent electrode 50 is arranged on part of the third surface 421 and the third side wall 423; the second bent electrode 52 is arranged on part of the fourth surface 422 and the fourth side wall 424; and the second encapsulating material 48 wraps the second piezoelectric material layer 42, part of the first bent electrode 50, and part of the second bent electrode 52. In an embodiment, as shown in FIG. 5A, the first bent electrode 50 further covers part of the fourth surface 422 and has a fourth gap s4 from the second bent electrode 52 located on the fourth surface 422.

Continuing with the above description, in correspondence to the first outer interdigital portion 222 of the first piezoelectric assembly 16A, part of the first bent electrode 50, located on the third surface 421, of the second piezoelectric assembly 40A is electrically connected to the first conductive pattern 141, and is, for example, also directly adhered to the first conductive pattern 141 by an extremely thin bonding layer 28. In correspondence to the planar piezoelectric vibration module 10B according to the third embodiment, the planar piezoelectric vibration module 10D includes the conductive structure 30A, where the conductive structure 30A includes the plurality of conductive columns 301 and the plurality of second conductive sub-layers 303. Each of the plurality of second conductive sub-layers 303 is connected to the second outer interdigital portion 242 of the first piezoelectric assembly 16A and part of the second bent electrode 52 of the second piezoelectric assembly 40A; and the plurality of conductive columns 301 penetrate through the insulating filling layer 18 near the first piezoelectric assembly 16A and the second piezoelectric assembly 40A, respectively, and the conductive columns 301 have one terminals connected to the second conductive sub-layers 303 and the other terminals connected to the second conductive pattern 142. The second outer interdigital portion 242 is electrically connected to the second conductive pattern 142 by the corresponding conductive column 301 near the first piezoelectric assembly 16A and the second conductive sub-layer 303 connected, and the second bent electrode 52 is electrically connected to the second conductive pattern 142 by the corresponding conductive column 301 near the second piezoelectric assembly 40A and the second conductive sub-layer 242 connected.

In other words, the first piezoelectric assembly 16A and the second piezoelectric assembly 40A may be optionally arranged in the planar piezoelectric vibration module 10D according to the fifth embodiment, where the second piezoelectric assembly 40A includes a layer of piezoelectric body (i.e. the second piezoelectric material layer 42), the first piezoelectric assembly 16A optionally includes, for example, five layers of sub-piezoelectric bodies 205, or the first piezoelectric assembly 16A may be replaced with the above first piezoelectric assembly 16B (as shown in FIG. 4) that includes, for example, six layers of sub-piezoelectric bodies 205. In addition, the number of first piezoelectric assemblies 16A (or 16B) and the number of second piezoelectric assemblies 40A are not limited to one, so that two or a plurality of first piezoelectric assemblies 16A (and/or 16B) or two or a plurality of second piezoelectric assemblies 40A can be arranged as required.

Further, as shown in FIG. 5B, a planar piezoelectric vibration module 10D′ further includes a conductive structure 30A′, where the conductive structure 30A′ includes a plurality of conductive columns 301′ and a plurality of second conductive sub-layers 303′, the plurality of conductive columns 301′ penetrate through the insulating filling layer 18 near the first piezoelectric assembly 16A and the second piezoelectric assemblies 40A, respectively, and the conductive columns 301′ have one terminals connected to the second conductive sub-layers 303′ and the other terminals connected to the first conductive pattern 141. The first extended interdigital portion 224 is electrically connected to the second conductive pattern 141 by the corresponding conductive column 301′ near the first piezoelectric assembly 16A and the second conductive sub-layer 303′ connected, and the first bent electrode 50 is electrically connected to the first conductive pattern 141 by the corresponding conductive column 301′ near the second piezoelectric assembly 40A and the second conductive sub-layer 303′ connected. Through the arrangement of the conductive structure 30A′, it is possible to avoid the situation where the first piezoelectric assembly 16A and the second piezoelectric assembly 40A are unable to operate as the first outer interdigital portion 222 or the first bent electrode 50 cannot form electric field induction with the first conductive pattern 141 due to the excessive thickness of the bonding layer 28.

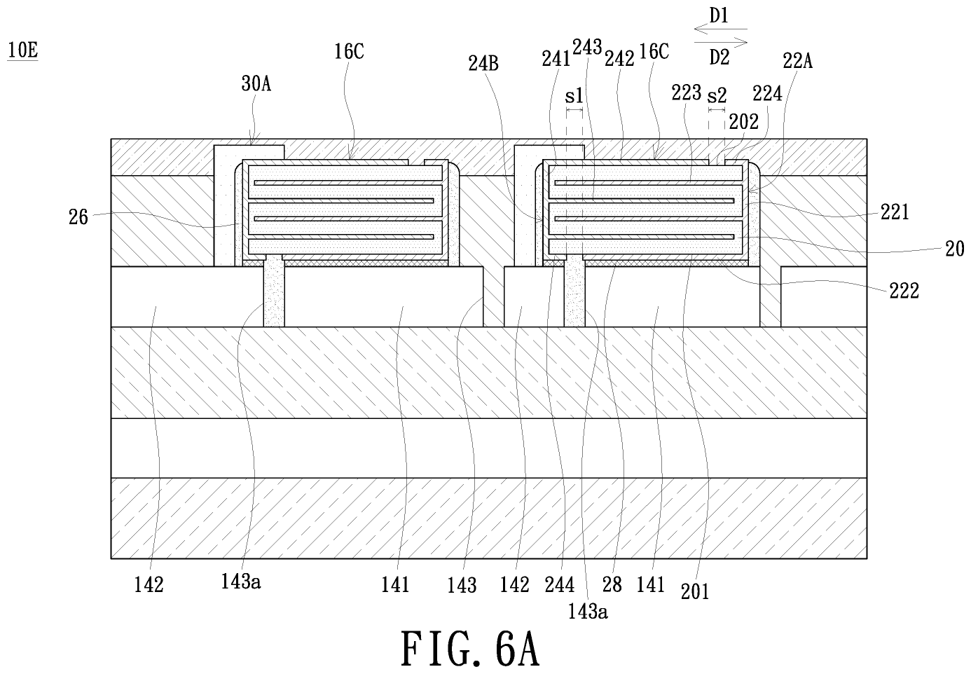

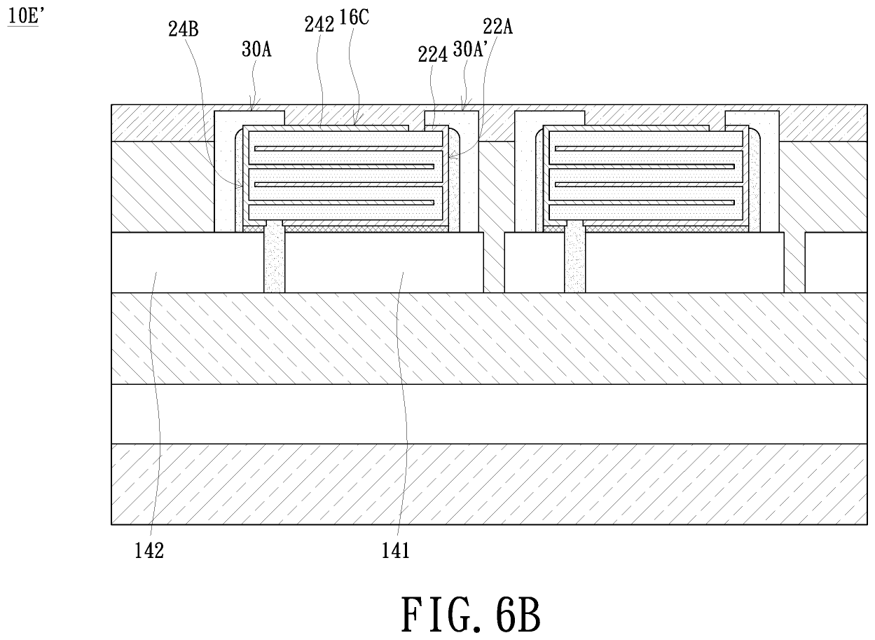

FIG. 6A and FIG. 6B are schematic sectional views of a planar piezoelectric vibration module according to a sixth embodiment of the present invention. As shown in FIG. 6A, there is a difference between a planar piezoelectric vibration module 10E according to a sixth embodiment and the planar piezoelectric vibration module 10B according to the third embodiment that the planar piezoelectric vibration module 10E according to the sixth embodiment has first piezoelectric assemblies 16C of different structures, where compared with the first piezoelectric assembly 16A, the first piezoelectric assembly 16C has second electrodes 24B of different structures, and therefore the arrangement of the above conductive structure 30A (marked in FIG. 3) is omitted due to the design of the second electrodes 24B. As shown in FIG. 6A, the first electrode 22A includes the first side portion 221, the first outer interdigital portion 222, the first inner interdigital portion 223, and the first extended interdigital portion 224, and the second electrode 24B includes a second extended interdigital portion 244 in addition to the second side portion 241, the second outer interdigital portion 242, and the second inner interdigital portion 243. The second extended interdigital portion 244, the second inner interdigital portion 243, and the second outer interdigital portion 242 are connected to the second side portion 241, and the second inner interdigital portion 243 is located between the second outer interdigital portion 242 and the second extended interdigital portion 244. In an embodiment, the extension length of the first extended interdigital portion 224 in the first direction D1 is less than the extension length of the first inner interdigital portion 223 in the first direction D1, and an extension length of the second extended interdigital portion 244 in the second direction D2 is less than the extension length of the second inner interdigital portion 243 in the second direction D2. The first outer interdigital portion 222 of the first electrode 22A and the second extended interdigital portion 244 of the second electrode 24B jointly cover the first surface 201, and there is a first gap s1 between the first outer interdigital portion 222 and the second extended interdigital portion 244; and the first extended interdigital portion 224 of the first electrode 22A and the second outer interdigital portion 242 of the second electrode 24B jointly cover the second surface 202, and there is the second gap s2 between the first extended interdigital portion 224 and the second outer interdigital portion 242.

Continuing with the above description, the first conductive pattern 141 and the second conductive pattern 142 are staggered through the distribution of the insulating groove 143, where the first gap s1, for example, corresponds to part of an insulating groove 143a, the first outer interdigital portion 222 of the first piezoelectric assembly 16C is directly adhered to the first conductive pattern 141 located on one side of the insulating groove 143a by, for example, an extremely thin bonding layer 28, and the second extended interdigital portion 244 arranged on the same first surface 201 as the first outer interdigital portion 222 is also directly adhered to the second conductive pattern 142 located on the other side of the insulating groove 143a by, for example, an extremely thin bonding layer 28. In addition, the first encapsulating material 26 of the first piezoelectric assembly 16C wraps the first piezoelectric material layer 20, part of the first electrode 22A, and part of the second electrode 24B, and is further filled in the insulating groove 143a and the first gap s1 to insulate the first outer interdigital portion 222 and the second extended interdigital portion 244 arranged on the same first surface 201. Furthermore, a part of the insulating groove 143 located between two first piezoelectric assemblies 16C is filled with the insulating filling layer 18 to insulate the first conductive pattern 141 and the second conductive pattern 142.

In an embodiment, as shown in FIG. 6A, the coverage area of the second outer interdigital portion 242 on the second surface 202 is greater than the coverage area of the first extended interdigital portion 224 on the second surface 202, and a coverage area of the first outer interdigital portion 222 on the first surface 201 is greater than a coverage area of the second extended interdigital portion 244 on the first surface 201. However, it is not limited thereto. In an embodiment not shown, the coverage area of the first extended interdigital portion 224 on the second surface 202 is greater than the coverage area of the second outer interdigital portion 242 on the second surface 202, and the coverage area of the second extended interdigital portion 244 on the first surface 201 is greater than the coverage area of the first outer interdigital portion 222 on the first surface 201. In an embodiment, as shown in FIG. 6A, the planar piezoelectric vibration module 10E further includes a protective layer 32 that is arranged on the insulating filling layer 18 and covers a plurality of first piezoelectric assemblies 16C.

In an embodiment, as shown in FIG. 6A, when the coverage area of the second extended interdigital portion 244 on the first surface 201 is too small, the conductive structure 30A may also be optionally further arranged to electrically connect the second outer interdigital portion 242 of the second electrode 24B to the second conductive pattern 142, in order to avoid the situation that the second extended interdigital portion 244 is unable to effectively form electric field induction with the second conductive pattern 142. The structure of the conductive structure 30A has been disclosed in the above embodiments and will not be repeated herein.

Furthermore, as shown in FIG. 6B, a planar piezoelectric vibration module 10E′ further includes the conductive structure 30A′ in addition to the conductive structure 30A for electrically connecting the second outer interdigital portion 242 of the second electrode 24B to the second conductive pattern 142, and the first extended interdigital portion 224 of the first electrode 22A is electrically connected to the first conductive pattern 141 by the conductive structure 30A′. The structure of the conductive structure 30A′ has been disclosed in the above embodiments that will not be repeated herein.

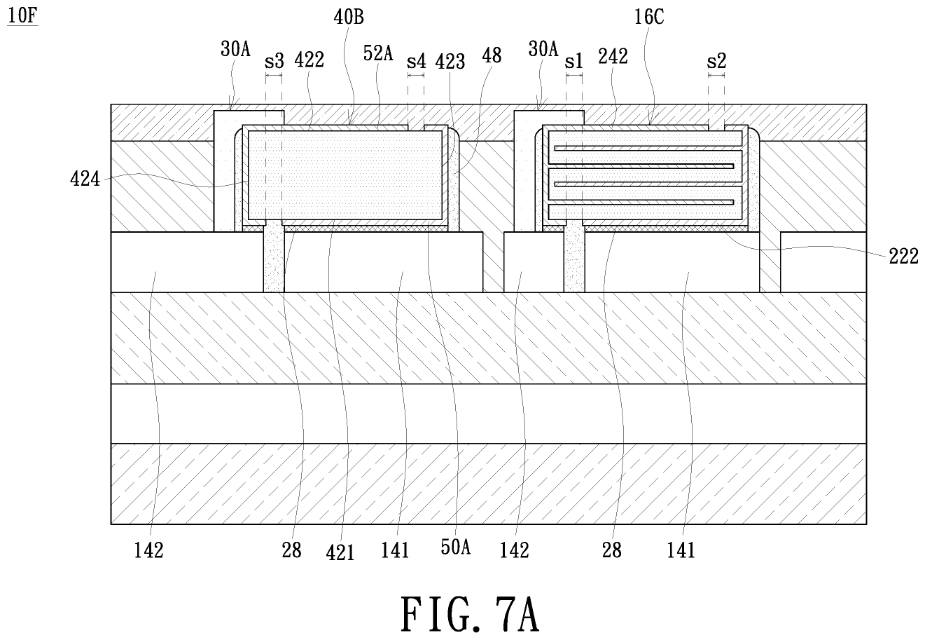

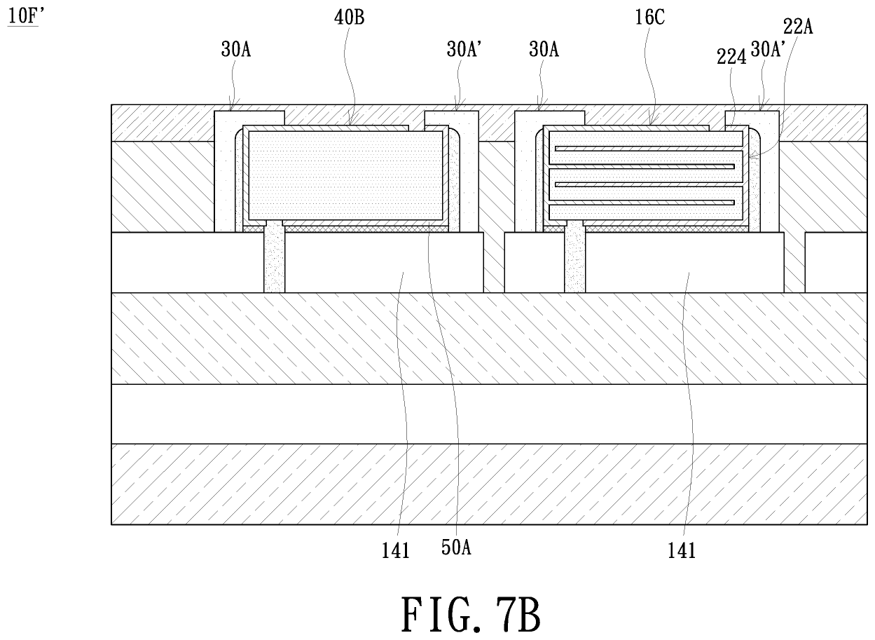

FIG. 7A and FIG. 7B are schematic sectional views of a planar piezoelectric vibration module according to a seventh embodiment of the present invention. As shown in FIG. 7A, there is a difference between a planar piezoelectric vibration module 10F according to a seventh embodiment and the planar piezoelectric vibration module 10E according to the sixth embodiment that the planar piezoelectric vibration module 10F according to the seventh embodiment further includes a second piezoelectric assembly 40B, where the second piezoelectric assembly 40B includes a second piezoelectric material layer 42, a first bent electrode 50A, a second bent electrode 52A, and a second encapsulating material 48. The second piezoelectric material layer 42 includes a third surface 421 and a fourth surface 422 opposite to each other and a third side wall 423 and a fourth side wall 424 opposite to each other, where the third side wall 423 and the fourth side wall 424 are connected to the third surface 421 and the fourth surface 422; the first bent electrode 50A is arranged on one part of the third surface 421, the third side wall 423, and one part of the fourth surface 422; the second bent electrode 52A is arranged on the other part of the fourth surface 422, the fourth side wall 424, and the other part of the third surface 421; and the second encapsulating material 48 wraps the second piezoelectric material layer 42, part of the first bent electrode 50A, and part of the second bent electrode 52A. In an embodiment, there is a third gap s3 between part of the first bent electrode 50A and part of the second bent electrode 52A located on the same third surface 421, and there is a fourth gap s4 between part of the first bent electrode 50A and part of the second bent electrode 52A located on the same fourth surface 422.

Continuing with the above description, in correspondence to the situation where the first outer interdigital portion 222 and the second extended interdigital portion 244 of the first piezoelectric assembly 16C are directly adhered to the first conductive pattern 141 and the second conductive pattern 142 by, for example, the extremely thin bonding layer 28, respectively, part of the first bent electrode 50A and part of the second bent electrode 52A, located on the same plane (the third surface 421), of the second piezoelectric assembly 40B are also directly adhered to the first conductive pattern 141 and the second conductive pattern 142 by, for example, an extremely thin bonding layer 28, respectively.

In an embodiment, as shown in FIG. 7A, the conductive structure 30A may be optionally further arranged, the second outer interdigital portion 242 of the first piezoelectric assembly 16C is electrically connected to the second conductive pattern 142 by the conductive structure 30A, and the second bent electrode 52A of the second piezoelectric assembly 40B is also electrically connected to the second conductive pattern 142 by the conductive structure 30A. The structure of the conductive structure 30A has been disclosed in the above embodiments that will not be repeated herein.

Further, as shown in FIG. 7B, a planar piezoelectric vibration module 10F′ further includes the conductive structure 30A′ in addition to the conductive structure 30A, the first extended interdigital portion 224 of the first electrode 22A of the first piezoelectric assembly 16C is electrically connected to the first conductive pattern 141 by the conductive structure 30A′, and the first bent electrode 50A of the second piezoelectric assembly 40B is also electrically connected to the first conductive pattern 141 by the conductive structure 30A′. The structure of the conductive structure 30A′ has been disclosed in the above embodiments that will not be repeated herein.

According to the above description, through the design of the inner interdigital portions of the planar piezoelectric vibration module according to the embodiments of the present invention, the planar piezoelectric assembly may have a plurality of layers of sub-piezoelectric bodies; and the sub-piezoelectric bodies may have different thicknesses and resonant frequencies, so that the planar piezoelectric assembly has various modes, that is, the planar piezoelectric assembly has various resonant frequencies. According to the piezoelectric vibration module according to the present invention, through the reasonable design of the thicknesses of the sub-piezoelectric bodies, the resonant frequencies of the sub-piezoelectric bodies in the planar piezoelectric assembly get close to each other and are coupled, the sound pressure is increased, and the simultaneous operation is performed within a wider frequency range, so that the combined frequency response does not generate discontinuous and deep troughs, and the composite multi-mode vibration will be formed within this frequency band, that is, the working bandwidth of the piezoelectric vibration module can be effectively expanded to achieve high-frequency and broadband transmission of sound waves.

Although the present invention has been disclosed above with the embodiments, it is not intended to limit the present invention. Those with ordinary skill in the art of the present invention can make some changes and modifications without departing from the spirit and scope of the present invention. Therefore, the protection scope of the present invention should be defined by the scope of the appended claims.

What is claimed is:

1. A planar piezoelectric vibration module, comprising:
an insulating bottom layer;
a first conductive layer, arranged on the insulating bottom layer, wherein the first conductive layer comprises a first conductive pattern, a second conductive pattern, and an insulating groove, and the insulating groove is provided between the first conductive pattern and the second conductive pattern;
at least a first piezoelectric assembly, arranged on the first conductive layer, wherein the at least a first piezoelectric assembly comprises a first piezoelectric material layer, a first electrode, a second electrode, and a first encapsulating material, wherein
the first piezoelectric material layer comprises a first surface and a second surface opposite to each other and a first side wall and a second side wall opposite to each other, the first side wall and the second side wall are connected to the first surface and the second surface, the first side wall faces the second side wall in a first direction, the second side wall faces the first side wall in a second direction,
the first electrode comprises a first side portion, a first outer interdigital portion, and at least a first inner interdigital portion, the first outer interdigital portion and the at least a first inner interdigital portion are connected to the first side portion, the first side portion is arranged on the first side wall, the first outer interdigital portion covers part of the first surface, the at least a first inner interdigital portion penetrates through the first piezoelectric material layer along the first direction, the first outer interdigital portion is electrically connected to the first conductive pattern,
the second electrode is electrically connected to the second conductive pattern and comprises a second side portion, a second outer interdigital portion, and at least a second inner interdigital portion, the second outer interdigital portion and the at least a second inner interdigital portion are connected to the second side portion, the second side portion is arranged on the second side wall, the second outer interdigital portion covers part of the second surface, the at least a second inner interdigital portion penetrates through the first piezoelectric material layer along the second direction, the first outer interdigital portion, the at least a second inner interdigital portion, the at least a first inner interdigital portion, and the second outer interdigital portion are arranged in a mutual interdigital manner,
the first encapsulating material wraps the first piezoelectric material layer, part of the first electrode, and part of the second electrode, and exposes at least the first outer interdigital portion and the second outer interdigital portion; and
an insulating filling layer, arranged on the first conductive layer and at least around the at least a first piezoelectric assembly.

2. The planar piezoelectric vibration module according to claim 1, wherein an extension length of the at least a first inner interdigital portion in the first direction is equal to an extension length of the second outer interdigital portion in the second direction, and an extension length of the at least a second inner interdigital portion in the second direction is equal to an extension length of the first outer interdigital portion in the first direction.

3. The planar piezoelectric vibration module according to claim 1, wherein the insulating filling layer is further filled in the insulating groove, the planar piezoelectric vibration module further comprises a conductive structure that penetrates through the insulating filling layer, and the second outer interdigital portion and the second conductive pattern of the second electrode are electrically connected by the conductive structure.

4. The planar piezoelectric vibration module according to claim 3, further comprising a protective layer that is arranged on the insulating filling layer and covers the at least a first piezoelectric assembly and the conductive structure.

5. The planar piezoelectric vibration module according to claim 1, wherein the first electrode further comprises a first extended interdigital portion connected to the first side portion, the at least a first inner interdigital portion is located between the first outer interdigital portion and the first extended interdigital portion, the first outer interdigital portion of the first electrode covers part of the first surface, the first extended interdigital portion and the second outer interdigital portion of the second electrode jointly cover the second surface, and there is a second gap between the first extended interdigital portion and the second outer interdigital portion.

6. The planar piezoelectric vibration module according to claim 5, wherein a coverage area of the second outer interdigital portion on the second surface is greater than a coverage area of the first extended interdigital portion on the second surface, and an extension length of the second outer interdigital portion in the second direction is less than an extension length of the at least a second inner interdigital portion in the second direction.

7. The planar piezoelectric vibration module according to claim 5, wherein a coverage area of the first extended interdigital portion on the second surface is greater than a coverage area of the second outer interdigital portion on the second surface, and an extension length of the first extended interdigital portion in the first direction is less than an extension length of the at least a first inner interdigital portion in the first direction.

8. The planar piezoelectric vibration module according to claim 5, wherein the insulating filling layer is further filled in the insulating groove, the planar piezoelectric vibration module further comprises at least a conductive structure that penetrates through the insulating filling layer, and the second outer interdigital portion of the second electrode and the second conductive pattern are electrically connected by the at least a conductive structure.

9. The planar piezoelectric vibration module according to claim 8, wherein the at least a conductive structure further electrically connects the first extended interdigital portion of the first electrode to the first conductive pattern.

10. The planar piezoelectric vibration module according to claim 5, further comprising a protective layer arranged on the insulating filling layer, wherein the protective layer covers the at least a first piezoelectric assembly and a conductive structure, and fills the second gap.

11. The planar piezoelectric vibration module according to claim 1, wherein the first electrode further comprises a first extended interdigital portion connected to the first side portion, the at least a first inner interdigital portion is located between the first outer interdigital portion and the first extended interdigital portion, the second electrode further comprises a second extended interdigital portion connected to the second side portion, the at least a second inner interdigital portion is located between the second outer interdigital portion and the second extended interdigital portion, the first outer interdigital portion of the first electrode and the second extended interdigital portion of the second electrode jointly cover the first surface, there is a first gap between the first outer interdigital portion and the second extended interdigital portion, the first extended interdigital portion of the first electrode and the second outer interdigital portion of the second electrode jointly cover the second surface, and there is a second gap between the first extended interdigital portion and the second outer interdigital portion.

12. The planar piezoelectric vibration module according to claim 11, wherein a coverage area of the second outer interdigital portion on the second surface is greater than a coverage area of the first extended interdigital portion on the second surface, and a coverage area of the first outer interdigital portion on the first surface is greater than a coverage area of the second extended interdigital portion on the first surface.

13. The planar piezoelectric vibration module according to claim 11, wherein the second extended interdigital portion of the second electrode is electrically connected to the second conductive pattern, and the first encapsulating material is further filled in one part of the insulating groove and the first gap.

14. The planar piezoelectric vibration module according to claim 13, wherein the insulating filling layer is further filled in the other part of the insulating groove, the planar piezoelectric vibration module further comprises at least a conductive structure that penetrates through the insulating filling layer and is electrically connected to the second outer interdigital portion of the second electrode and the second conductive pattern.

15. The planar piezoelectric vibration module according to claim 14, wherein the at least a conductive structure further electrically connects the first extended interdigital portion of the first electrode to the first conductive pattern.

16. The planar piezoelectric vibration module according to claim 11, further comprising a protective layer arranged on the insulating filling layer, wherein the protective layer covers the at least a first piezoelectric assembly and fills the second gap.

17. The planar piezoelectric vibration module according to claim 1, wherein there are a plurality of first piezoelectric assemblies, the planar piezoelectric vibration module further comprises a conductive structure, the conductive structure comprises at least a conductive column and a second conductive layer, the second conductive layer is electrically connected to the second outer interdigital portions of the plurality of first piezoelectric assemblies, and the at least a conductive column penetrates through the insulating filling layer and is electrically connected to the second conductive layer and the second conductive pattern.

18. The planar piezoelectric vibration module according to claim 1, wherein there are a plurality of first piezoelectric assemblies, the planar piezoelectric vibration module further comprises a plurality of conductive structures that penetrate through the insulating filling layer, and each of the plurality of conductive structures electrically connects the second outer interdigital portion of each of the plurality of piezoelectric assemblies to the second conductive pattern.

19. The planar piezoelectric vibration module according to claim 1, further comprising at least a second piezoelectric assembly, wherein the at least a second piezoelectric assembly comprises a second piezoelectric material layer, a first planar electrode, a second planar electrode, and a second encapsulating material, the first planar electrode and the second planar electrode are arranged on two opposite sides of the second piezoelectric material layer, respectively, the second encapsulating material wraps part of the second piezoelectric material layer and exposes at least the first planar electrode and the second planar electrode, and the first planar electrode is electrically connected to the first conductive pattern; and the planar piezoelectric vibration module further comprises a conductive structure, wherein the conductive structure comprises at least a conductive column and a second conductive layer, the second conductive layer is electrically connected to the second planar electrode and the second outer interdigital portion, and the at least a conductive column penetrates through the insulating filling layer and is electrically connected to the second conductive layer and the second conductive pattern.

20. The planar piezoelectric vibration module according to claim 1, further comprising at least a second piezoelectric assembly, wherein the at least a second piezoelectric assembly comprises:
a second piezoelectric material layer, comprising a third surface and a fourth surface opposite to each other and a third side wall and a fourth side wall opposite to each other, wherein the third side wall and the fourth side wall are connected to the third surface and the fourth surface;
a first bent electrode, arranged on part of the third surface and the third side wall;
a second bent electrode, arranged on part of the fourth surface and the fourth side wall; and
a second encapsulating material, wrapping the second piezoelectric material layer, part of the first bent electrode, and part of the second bent electrode,
wherein part of the first bent electrode located on the third surface is electrically connected to the first conductive pattern; and the planar piezoelectric vibration module further comprises a plurality of conductive structures that penetrate through the insulating filling layer and electrically connect the second outer interdigital portion of the at least a first piezoelectric assembly and part of the second bent electrode to the second conductive pattern, respectively.

21. The planar piezoelectric vibration module according to claim 20, wherein the plurality of conductive structures further electrically connect the first extended interdigital portion of the at least a first piezoelectric assembly and part of the first bent electrode to the first conductive pattern, respectively.

22. The planar piezoelectric vibration module according to claim 20, wherein the second bent electrode further covers part of the third surface and has a third gap from the first bent electrode located on the third surface.

23. The planar piezoelectric vibration module according to claim 20, wherein the first bent electrode further covers part of the fourth surface and has a fourth gap from the second bent electrode located on the fourth surface.

24. The planar piezoelectric vibration module according to claim 1, wherein the first outer interdigital portion is arranged on the first conductive pattern by a bonding layer.

25. The planar piezoelectric vibration module according to claim 1, further comprising a third conductive layer arranged on the other opposite side, away from the first conductive layer, of the insulating bottom layer.

26. The planar piezoelectric vibration module according to claim 1, further comprising at least an auxiliary layer arranged on the other opposite side, away from the insulating bottom layer, of a third conductive layer.
